(19) United States
(12) Patent Application Publication
(10) Pub. No.: US 2025/0228000 A1
(43) Pub. Date: Jul. 10, 2025

(54) DISPLAY DEVICE

(71) Applicant: InnoLux Corporation, Miao-Li County (TW)

(72) Inventors: Cheng-Tso CHEN, Miao-Li County (TW); Hung-Kun CHEN, Miao-Li County (TW); Chung-Le CHEN, Miao-Li County (TW); Ting-Yao CHU, Miao-Li County (TW)

(21) Appl. No.: 18/980,384

(22) Filed: Dec. 13, 2024

Related U.S. Application Data
(60) Provisional application No. 63/617,877, filed on Jan. 5, 2024.

(30) Foreign Application Priority Data
Sep. 3, 2024 (CN) 202411225033.6

(51) Int. Cl. H10D 86/40; G09G 3/20

(52) U.S. Cl. CPC H10D 86/441; G09G 3/20; G09G 2300/026

(57) ABSTRACT

A display device includes: a substrate having an active area including a first area and a second area; a first driving circuit disposed adjacent to the first area; a second driving circuit disposed adjacent to the second area; first scan lines electrically connected to the first driving circuit; second scan lines electrically connected to the second driving circuit, wherein the first scan lines and the second scan lines extend along a first direction; first display units disposed in the first area and respectively electrically connected to the first scan lines and electrically separated from the second scan lines; and second display units disposed in the second area and respectively electrically connected to the second scan lines and electrically separated from the first scan lines. The active area is disposed between the first driving circuit and the second driving circuit in the first direction.

### CROSS-REFERENCE TO RELATED APPLICATIONS

This application claims the benefit of filing date of U.S. Provisional Application Ser. No. 63/617,877 filed Jan. 5, 2024 under 35 USC § 119(e)(1), and also claims the benefit of the Chinese Patent Application Serial Number 202411225033.6, filed on Sep. 3, 2024, the subject matter of which is incorporated herein by reference.

### BACKGROUND

### Field of the Disclosure

The present disclosure relates to a display device and, more particularly, to a display device with multi-zone display.

### Description of Related Art

With the advance of technology, in order to meet various needs, manufacturers continue to improve and research display devices. Typically, to display different images in one display device, a plurality of display panels can be tiled and assembled through a tiling process.

However, in a tiled and assembled display device, there are problems such as discontinuous images caused by non-display areas between different display panels, or the display device being prone to electrostatic discharge risk that causes damage to components within the device.

Therefore, there is an urgent need to provide a display device in order to alleviate and/or obviate the aforementioned defects.

### SUMMARY

The present disclosure provides a display device, which comprises: a substrate including an active area having a first area and a second area; a first driving circuit disposed adjacent to the first area of the active area; a second driving circuit disposed adjacent to the second area of the active area; a plurality of first scan lines extending along a first direction in the active area, wherein the first scan lines are electrically connected to the first driving circuit; a plurality of second scan lines extending along the first direction in the active area, wherein the second scan lines are electrically connected to the second driving circuit; a plurality of first display units disposed in the first area of the active area, wherein the first display units are respectively electrically connected to the first scan lines and electrically separated from the second scan lines; and a plurality of second display units disposed in the second area of the active area, wherein the second display units are respectively electrically connected to the second scan lines and are electrically separated from the first scan lines, wherein the first scan lines and the second scan lines are disposed in an interlaced manner and, in the first direction, the active area is disposed between the first driving circuit and the second driving circuit.

Other novel features of the disclosure will become more apparent from the following detailed description when taken in conjunction with the accompanying drawings.

### BRIEF DESCRIPTION OF DRAWINGS

FIG. 1 is a schematic diagram of a display device according to an embodiment of the present disclosure;

FIG. 2A to FIG. 2C are partial enlarged views of FIG. 1;

FIG. 2D is a partial enlarged view of FIG. 2A;

FIG. 3 is a schematic diagram of a display device according to an embodiment of the present disclosure;

FIG. 4A to FIG. 4C are partial enlarged views of FIG. 3;

FIG. 4D is a partial enlarged view of FIG. 4B;

FIG. 5 is a schematic diagram of a display device according to an embodiment of the present disclosure;

FIG. 6A to FIG. 6D are partial enlarged views of FIG. 5; and

FIG. 6E is a partial enlarged view of FIG. 6D.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided. In addition, in the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. A “first” element and a “second” element may appear together in the same component, or separately in different components. The existence of an element with a larger ordinal number does not necessarily mean the existence of another element with a smaller ordinal number.

In the entire specification and appended claims of the present disclosure, certain words are used to refer to specific components. Those skilled in the art should understand that electronic device manufacturers may refer to the same components by different names. The present disclosure does not intend to distinguish those components with the same function but different names. In the following description and claims, words such as “comprising”, “including”, and “having” are open type words, so they should be interpreted as meaning “including but not limited to”. Therefore, when the terms “comprising”, “including” and/or “having” are used in the description of the present disclosure, they specify the existence of corresponding features, regions, steps, operations and/or components, but do not exclude the existence of one or more corresponding features, regions, steps, operations and/or components.

In the description, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values in between the first value and the second value.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

In the present disclosure, the distance, width, length and thickness can be measured by using an optical microscope, and the distance, width, length and thickness can be measured by the cross-sectional image in an electron microscope, but it is not limited thereto. In addition, there may be a certain error in any two values or directions used for comparison. If the first value is equal to the second value, it implies that there may be an error of about 10% between the first value and the second value. If the first direction is perpendicular to the second direction, the angle between the first direction and the second direction may be 80 to 100 degrees. If the first direction is parallel to the second direction, the angle between the first direction and the second direction may be 0 to 10 degrees.

It should be noted that the technical solutions provided by the different embodiments described hereinafter may be used interchangeably, combined or mixed to form another embodiment without violating the spirit of the present disclosure.

The display device of the present disclosure may be a non-self-luminous display device or a self-luminous display device, such as a liquid crystal display, a cholesteric liquid crystal display, an electro-phoretic display, an organic light emitting diode display, light emitting diode display, but not limited thereto. The display device may include a light emitting diode, a light conversion layer or other suitable materials, or a combination thereof, but not limited thereto. The light emitting diode may include, for example, an organic light emitting diode (OLED), a sub-millimeter light emitting diode (mini LED), a micro-light emitting diode (micro LED) or a quantum dot light emitting diode (quantum dot LED, which may include QLED, QDLED), but not limited thereto.

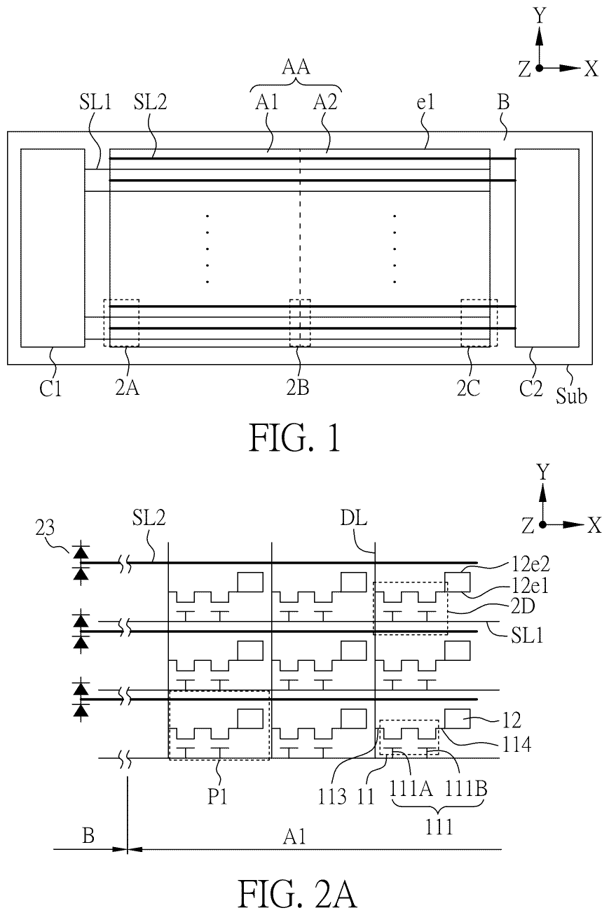

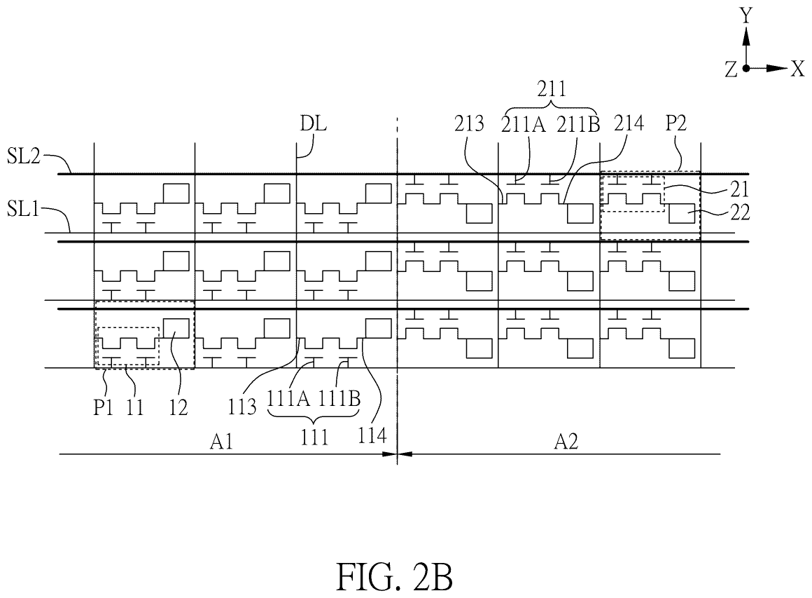

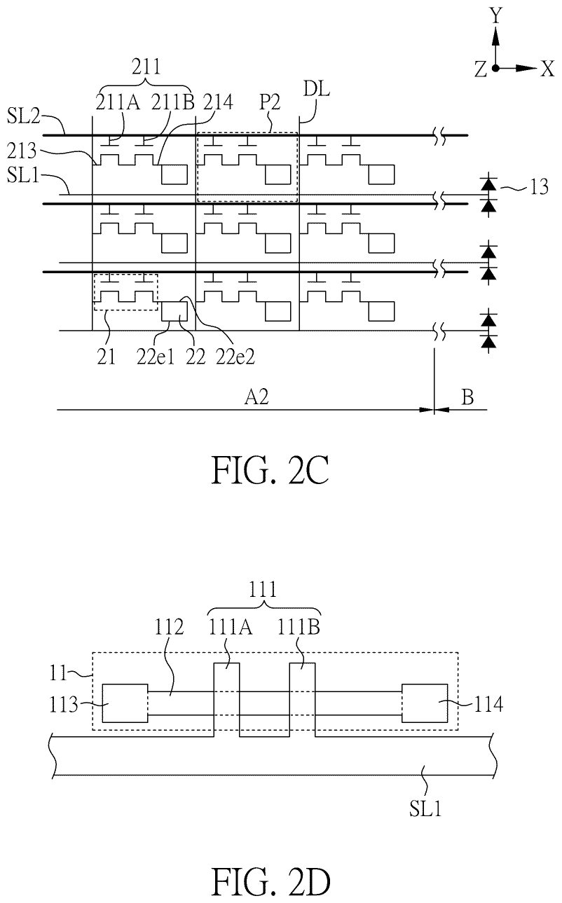

FIG. 1 is a schematic diagram of a display device according to an embodiment of the present disclosure, FIG. 2A to FIG. 2C are partial enlarged views of FIG. 1, and FIG. 2D is a partial enlarged view of FIG. 2A, wherein, for convenience of explanation, some components are omitted in the figures.

In one embodiment of the present disclosure, as shown in FIG. 1, the display device may include: a substrate Sub including an active area AA, and a peripheral area B surrounding the active area AA, wherein the active area AA includes a first area A1 and a second area A2; a first driving circuit C1 arranged adjacent to the first area A1 of the active area AA; a second driving circuit C2 arranged adjacent to the second area A2 of the active area AA; a plurality of first scan lines SL1 extending along a first direction X in the active area AA, wherein the first scan lines SL1 are electrically connected to the first driving circuit C1; and a plurality of second scan lines SL2 extending along the first direction X in the active area, wherein the second scan lines SL2 are electrically connected to the second driving circuit C2. Furthermore, the first scan lines SL1 and the scan lines SL2 are arranged in an interlaced manner and, in the first direction X, the active area AA is disposed between the first driving circuit C1 and the second driving circuit C2.

In the present disclosure, the active area AA may include a plurality of display units. More specifically, the range of the active area AA may be defined by the edges of the display units. For example, in the active area AA, the upper edge e1 parallel to the first direction X may be defined by the line connecting the upper left corner of the upper leftmost display unit to the upper right corner of the upper rightmost display unit in the active area AA, and the length of the edge e1 may be the distance in the first direction X from the upper left corner of the upper left display unit to the upper right corner of the upper right display unit, wherein the length of at least one of the first scan line SL1 and the second scan line SL2 is greater than ¾ of the length of the edge e1, but the present disclosure is not limited thereto.

In one embodiment of the present disclosure, as shown in FIG. 2A to FIG. 2C, the display device may include a plurality of data lines DL extending along a second direction Y in the active area AA, wherein the first direction X is different from the second direction Y. The plurality of data lines DL intersect the plurality of first scan lines SL1 and the plurality of second scan lines SL2 to form a plurality of display units. In more detail, as shown in FIG. 2A and FIG. 2B, a plurality of data lines DL and a plurality of first scan lines SL1 are intersected to form a plurality of first display units P1. More specifically, the range of a first display unit P1 may be defined as the range enclosed by the center line of a data line DL to the center line of another data line DL adjacent thereto, and the center line of a first scan line SL1 to another first scan line SL1 adjacent thereto. The first display units P1 are arranged in the first area A1 of the active area AA, wherein the first display units P1 are respectively electrically connected to the first scan lines SL1 and electrically separated from the second scan lines SL2. As shown in FIG. 2B and FIG. 2C, a plurality of data lines DL and a plurality of second scan lines SL2 are intersected to form a plurality of second display units P2. Similar to the definition of the range of the first display unit P1, specifically, the range of a second display unit P2 may be defined as the range enclosed by the center lines of two adjacent data lines DL and the center lines of two adjacent second scan lines SL2. The second display units P1 are arranged in the second area A2 of the active area AA, wherein the second display units P2 are respectively electrically connected to the second scan lines SL2 and electrically separated from the first scan lines SL1. According to the description of this paragraph, the upper left corner of a display unit may be the intersection point of the center line of the data line DL on the left side of the display unit and the center line of the scan line on the upper side of the display unit, and the upper right corner of the display unit may be the intersection point of the center line of the data line DL on the right side of the display unit and the center line of the scan line on the upper side of the display unit. The other endpoints of the display unit may be defined in a similar manner.

In the present disclosure, by transmitting signals to the first display units P1 through the first scan lines SL1 electrically connected to the first driving circuit C1, and transmitting signals to the second display units P2 through the second scan lines SL2 electrically connected to the second driving circuit C2, it is able to realize, in the same display device, the effect of partitioning display through the first display units P1 disposed in the first area A1 and the second display units P2 disposed in the second area A2. In other words, in the same display device, the first display units P1 disposed in the first area A1 and the second display units P2 disposed in the second area A2 may respectively display different patterns. When the components or display units in one of the first area A1 and the second area A2 of the active area AA are defective, the display units in the other area may still display images. Therefore, the present disclosure may be used, for example, in aircraft or other high-end display devices. In addition, since the display device of the present disclosure does not realize the partitioning effect by tilting or assembling display panels, there will be no non-display area or discontinuous frame between the first area A1 and the second area A2.

In one embodiment of the present disclosure, as shown in FIG. 1, in the first direction X, the first area A1 of the active area AA is disposed between the second area A2 of the active area AA and the first driving circuit C1, and the second area A2 of the active area AA is disposed between the first area A1 of the active area AA and the second driving circuit C2. In one embodiment of the present disclosure, as shown in FIG. 1, the first driving circuit C1 and the second driving circuit C2 may be respectively disposed on the peripheral area B of the substrate Sub, but the present disclosure is not limited thereto. In other embodiments, the first driving circuit C1 may be selectively disposed on other substrates adjacent to the first area A1, and the second driving circuit C2 may be selectively disposed on other substrates adjacent to the second area A2.

In one embodiment of the present disclosure, as shown in FIG. 2A and FIG. 2B, one of the first display units P1 may include: a first transistor 11; and a first pixel electrode 12, wherein the first transistor 11 is electrically connected to the first pixel electrode 12. In more detail, as shown in FIG. 2D, the first transistor 11 may include: a first gate 111, a first semiconductor layer 112, a first electrode 113 and a second electrode 114, wherein the first gate 111 is electrically connected to one of the first scan lines SL1 and overlaps with a portion of the first semiconductor layer 112. In addition, as shown in FIG. 2A and FIG. 2D, the first electrode 113 is electrically connected to one of the data lines DL, and the second electrode 114 is electrically connected to the first pixel electrode 12. In one embodiment of the present disclosure, the first electrode 113 and the second electrode 114 may be electrically connected to one of the data lines DL and the first pixel electrode 12, respectively, through a conductive material (not shown).

Similarly, as shown in FIG. 2B and FIG. 2C, one of the second display units P2 may include: a second transistor 21; and a second pixel electrode 22, wherein the second transistor 21 is connected to the second pixel electrode 22. Similarly, the second transistor 21 may also have a structure as shown in FIG. 2D. The second transistor 21 may include: a second gate 211, a second semiconductor layer (not shown), and a third electrode 213 and a fourth electrode 214, wherein the second gate 211 is electrically connected to one of the second scan lines SL2 and overlaps with a portion of the second semiconductor layer (not shown). In addition, as shown in FIG. 2C, the third electrode 213 is electrically connected to one of the data lines DL, and the fourth electrode 214 is electrically connected to the second pixel electrode 22. In one embodiment of the present disclosure, the third electrode 213 and the fourth electrode 214 may be electrically connected to one of the data lines DL and the second pixel electrode 22, respectively, through a conductive material (not shown).

In one embodiment of the present disclosure, as shown in FIG. 2A, the first pixel electrode 12 has a first edge 12e1 and a second edge 12e2, and the first edge 12e1 is opposite to the second edge 12e2, wherein one of the scan lines SL1 is disposed adjacent to the first edge 12e1 and is electrically connected to the first transistor 11 corresponding to the first pixel electrode 12, and one of the second scan lines SL2 is disposed adjacent to the second edge 12e2. Similarly, as shown in FIG. 2C, the second pixel electrode 22 has a first edge 22e1 and a second edge 22e2, and the first edge 22e1 is opposite to the second edge 22e2, wherein one of the second scan lines SL2 is disposed adjacent to the second edge 22e2 and is electrically connected to the second transistor 21 corresponding to the second pixel electrode 22, and one of the first scan lines SL1 is disposed adjacent to an edge 22e1.

In one embodiment of the present disclosure, as shown in FIG. 2A and FIG. 2D, the first gate 111 may include branch portions 111A and 111B, and the branch portions 111A and 111B may be respectively electrically connected to the same one of the first scan lines SL1 and overlaps with a portion of the first semiconductor layer 112. The branch portions 111A and 111B may improve the driving effect of the first transistor 11. Similarly, as shown in FIG. 2C, the second gate 211 may also have branch portions (for example, 211A and 211B) as those shown in FIG. 2D, which will not be described again. In the present disclosure, as shown in FIG. 2D, the first gate 111 is exemplified by a top gate structure, but the present disclosure is not limited thereto. In other embodiments, the first gate 111 may also be a bottom gate structure.

In one embodiment of the present disclosure, as shown in FIG. 2A, the display device may include a second electrostatic discharge protection structure 23, which is disposed in the peripheral area B of the substrate Sub (as shown in FIG. 1) and electrically connected to the second scan line SL2. In one embodiment of the present disclosure, as shown in FIG. 1 and FIG. 2A, in the first direction X, the second electrostatic discharge protection structure 23 is disposed between the first driving circuit C1 and the first area A1. In one embodiment of the present disclosure, as shown in FIG. 2A, the second electrostatic discharge protection structure 23 may include diodes connected in series, but the present disclosure is not limited thereto. A plurality of diodes connected in series may be used to release static charges generated by the display device to avoid damage to components within the display device due to accumulation of static charges. In this embodiment, the second electrostatic discharge protection structure 23 shown in FIG. 2A is exemplified by two diodes connected in series, but the present disclosure is not limited thereto. In other embodiments, the number of diodes connected in series may be adjusted as needed, and the number of diodes in each second electrostatic discharge protection structure 23 may be the same or different.

Similarly, as shown in FIG. 2C, the display device may include a first electrostatic discharge protection structure 13, and the structure and function thereof may be the same as those of the aforementioned second electrostatic discharge protection structure 23, so that a detailed description is deemed unnecessary.

In the present disclosure, the first scan line SL1 and the second scan line SL2 may be of the same layer or different layers, and the materials of the first scan line SL1 and the second scan line SL2 may each include a metal material, a metal oxide material, an alloy thereof or a combination thereof, such as gold, silver, copper, palladium, platinum, ruthenium, aluminum, cobalt, nickel, titanium, molybdenum, manganese, indium zinc oxide (IZO), indium tin oxide (ITO), oxide Indium tin zinc oxide (ITZO), indium gallium zinc oxide (IGZO), aluminum zinc oxide (AZO) or a combination thereof, but the present disclosure is not limited thereto. In the present disclosure, the data line DL is in a different layer from the first scan line SL1 and the second scan line SL2, and the material of the data line DL may be similar to that of the first scan line SL1 or the second scan line SL2, which will not be described again here. In the present disclosure, the materials of the first gate 111 and the second gate 211 may be the same or different, and the first gate 111 and the second gate 211 may each include a metal material, a metal oxide material, an alloy thereof, or a combination thereof, such as gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), aluminum zinc oxide (AZO) or a combination thereof, but the present disclosure is not limited thereto. In the present disclosure, the materials of the first semiconductor layer 112 and the second semiconductor layer 212 may be the same or different, and the first semiconductor layer 112 and the second semiconductor layer 212 may each include amorphous silicon, polycrystalline silicon (such as low-temperature polycrystalline silicon (LTPS)) or oxide semiconductor (such as indium gallium zinc oxide (IGZO) or indium gallium oxide (IGO)), but the present disclosure is not limited thereto. In the present disclosure, the materials of the first pixel electrode 12 and the second pixel electrode 22 may be the same or different, and the first pixel electrode 12 and the second pixel electrode 22 may each include a transparent conductive material, such as indium zinc oxide (IZO), indium tin oxide (ITO), indium tin zinc oxide (ITZO), indium gallium zinc oxide (IGZO), aluminum zinc oxide (AZO) or a combination thereof, but the present disclosure is not limited thereto.

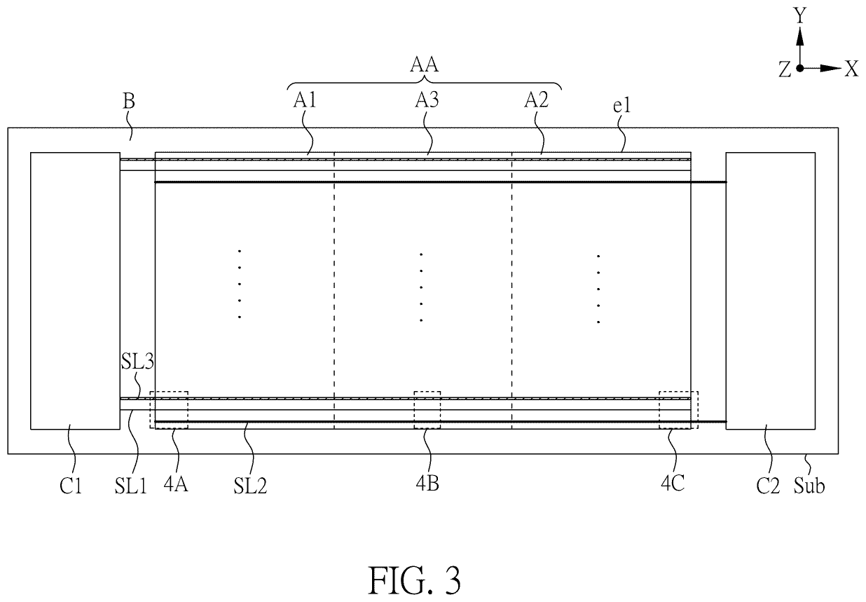

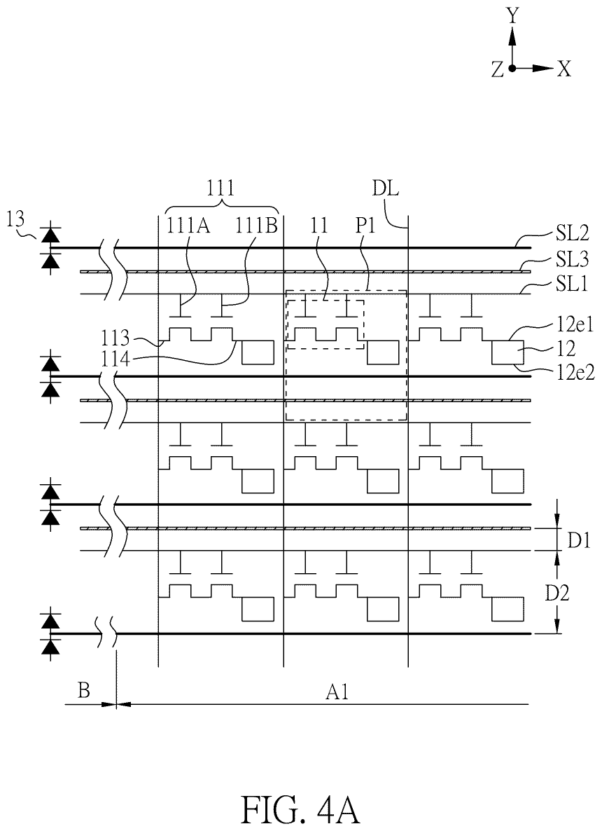

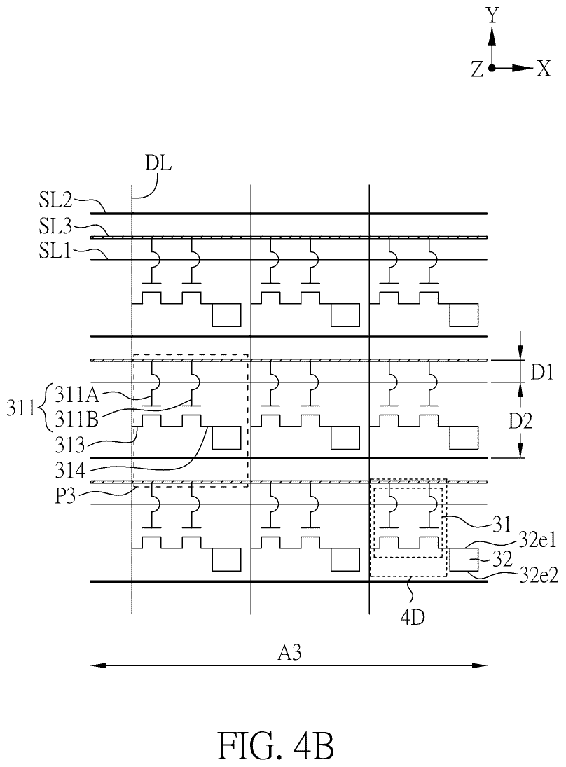

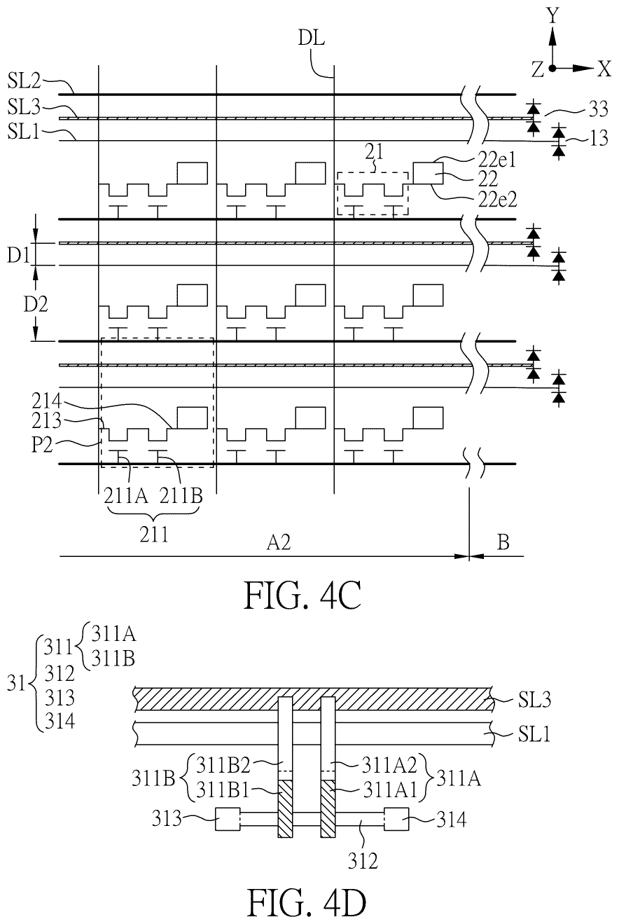

FIG. 3 is a schematic diagram of a display device according to an embodiment of the present disclosure, FIG. 4A to FIG. 4C are partial enlarged views of FIG. 3, and FIG. 4D is a partial enlarged view of FIG. 4B, wherein the display device of FIG. 3 is similar to that of FIG. 1 except for the following differences. In addition, for convenience of explanation, some components are omitted from the figures.

In one embodiment of the present disclosure, as shown in FIG. 3, the active area AA of the substrate Sub may include a third area A3 disposed between the first area A1 and the second area A2. The display device further includes: a plurality of third scan lines SL3 extending along the first direction X in the active area AA, wherein the third scan lines SL3 are electrically connected to the first driving circuit C1, but the present disclosure is not limited thereto. In some embodiments, the third scan line SL3 may be electrically connected to the second driving circuit C2.

In one embodiment of the present disclosure, as shown in FIG. 4A to FIG. 4C, in the second direction Y, one of the first scan lines SL1 is disposed between one of the second scan lines SL2 and one of the third the scan lines SL3, and the distance DI between the one of the first scan lines SL1 and the one of the third scan lines SL3 is smaller than the distance D1 between the one of the first scan lines SL1 and the one of the second scan lines SL2. In more detail, in the second direction Y, the second scan line SL2 and the third scan line SL3 are respectively disposed on two sides of the first scan line SL1, wherein there is a distance DI between the third scan line SL3 adjacent to the first scan line SL1 and the first scan line SL1, and there is a distance D2 between the second scan line SL2 adjacent to the first scan line SL1 and the first scan line SL1, where the distance DI is smaller than the distance D2.

In one embodiment of the present disclosure, as shown in FIG. 3, the active area AA has an edge e1 parallel to the first direction X, wherein the length of at least one of the first scan line SL1, the second scan line SL2 and the third the scan line SL3 is greater than ¾ of the length of the edge e1, but the present disclosure is not limited thereto.

In one embodiment of the present disclosure, as shown in FIG. 4A to FIG. 4C, a plurality of data lines DL and a plurality of third scan lines SL3 are intersected to form a plurality of third display units P3, and the third display units P3 are disposed in the third area A3 of the active area AA (as shown in FIG. 3). The first display units P1 are respectively electrically connected to the first scan lines SL1, and electrically separated from the second scan lines SL2 and the third scan lines SL3. The second display units P2 are respectively electrically connected to the second scan lines SL2, and electrically separated from the first scan lines SL1 and the third scan lines SL3. The third display units P3 are respectively electrically connected to the third scan lines SL3, and electrically separated from the first scan lines SL1 and the second scan lines SL2.

In the present disclosure, by transmitting signals to the first display units P1 through the first scan lines SL1 electrically connected to the first driving circuit C1, transmitting signals to the second display units P2 through the second scan lines SL2 electrically connected to the second driving circuit C2, and transmitting signals to the third display units P3 through the third scan lines SL3 electrically connected to the first driving circuit C1, it is able to realize, in the same display device, the effect of partitioning display through the first display units P1 disposed in the first area A1, the second display units P2 disposed in the second area A2, and the third display units P3 disposed in the third area A3. In other words, in the same display device, the first display units P1 disposed in the first area A1, the second display units P2 disposed in the second area A2, and the third display units P3 disposed in the third area A3 may respectively display different patterns. When the components or display units in one or two of the first area A1, the second area A2 and the third area A3 of the active area AA are defective, the display units in the other one area or the other two areas may still display images.

In this embodiment, as shown in FIG. 3, the third scan line SL3 is exemplified by being electrically connected to the first driving circuit C1. However, in other embodiments, the third scan line SL3 may be electrically connected to the second driving circuits C2, so that signals may be transmitted from the second driving circuit C2 to the third display unit P3 via the third scan line SL3 (as shown in FIG. 4B).

In one embodiment of the present disclosure, as shown in FIG. 4B, one of the third display units P3 may include: a third transistor 31; and a third pixel electrode 32, wherein the third transistor 31 is electrically connected to the third pixel electrode 32. In more detail, as shown in FIG. 4D, the third transistor 31 may include: a third gate 311, a third semiconductor layer 312, a fifth electrode 313 and a sixth electrode 314, wherein the third gate 311 is electrically connected to one of the third scan lines SL3 and overlaps with a portion of the third semiconductor layer 312. In addition, as shown in FIG. 4B and FIG. 4D, the fifth electrode 313 is electrically connected to one of the data lines DL, and the sixth electrode 314 is electrically connected to the third pixel electrode 32.

In one embodiment of the present disclosure, as shown in FIG. 4B and FIG. 4D, the third gate 311 may include branch portions 311A and 311B, and the branch portions 311A and 311B may be respectively electrically connected to the same one of the third scan lines SL3, and overlap with a portion of the third semiconductor layer 312. In more detail, as shown in FIG. 4D, the branch portion 311A includes a first portion 311A1 and a second portion 311A2, and the branch portion 311B includes a third portion 311B1 and a fourth portion 311B2, wherein the first portion 311A1 and the third portion 311B1 respectively overlap with a portion of the third semiconductor layer 312, the second portion 311A2 spans the first scan line SL1 to be electrically connected to the third scan line SL3 and the first portion 311A1, and the fourth portion 311B2 spans the first scan line SL1 to be electrically connected to the third scan line SL3 and the third portion 311B1. In the present disclosure, as shown in FIG. 4D, the third gate 311 is exemplified by a top gate structure, but the present disclosure is not limited thereto. In other embodiments, the third gate 311 may also be a bottom gate structure.

In the present disclosure, the materials of the first portion 311A1 and the third portion 311B1 may be different from the materials of the second portion 311A2 and the fourth portion 311B2. For example, the first portion 311A1 and the third portion 311B1 may include a metal material or an alloy thereof, or a combination thereof, the second portion 311A2 and the fourth portion 311B2 may include a transparent conductive material. The suitable metal material may be, for example, gold, silver, copper, palladium, platinum, ruthenium, aluminum, cobalt, nickel, titanium, molybdenum, manganese or a combination thereof, but the present disclosure is not limited thereto. The suitable transparent conductive material may be, for example, indium zinc oxide (IZO), indium tin oxide (ITO), indium tin zinc oxide (ITZO), indium gallium zinc oxide (IGZO), aluminum zinc oxide (AZO) or a combination thereof, but the preset disclosure is not limited thereto.

In one embodiment of the present disclosure, as shown in FIG. 4B, the third pixel electrode 32 has a first edge 32e1 and a second edge 32e2, and the first edge 32e1 is opposite to the second edge 32e2, wherein the one of the third scan lines SL3 is disposed adjacent to the first edge 32e1 and is electrically connected to the third transistor 31 corresponding to the third pixel electrode 32, and one of the second scan lines SL2 is disposed adjacent to the second edge 32e2.

In one embodiment of the present disclosure, as shown in FIG. 4C, the display device may include a third electrostatic discharge protection structure 33, which is disposed in the peripheral area B of the substrate Sub (as shown in FIG. 3) and is electrically connected to the third scan line. SL3. In one embodiment of the present disclosure, as shown in FIG. 3 and FIG. 4C, in the first direction X, the third electrostatic discharge protection structure 33 is disposed between the second driving circuit C2 and the second area A2. In the present disclosure, the third electrostatic discharge protection structure 33 may be similar to the first electrostatic discharge protection structure 13 or the second electrostatic discharge protection structure 23, and may be used to release the electrostatic charges generated by the display device, which will not be described again here.

In the present disclosure, the third scan line SL3 may be the same layer or a different layer from the first scan line SL1 and/or the second scan line SL2, and the material of the third scan line SL3 is similar to that of the first scan line SL1 or the second scan line SL2, so that a detailed description is deemed unnecessary. In the present disclosure, the material of the third gate 311 may be similar to that of the first gate 111 or the second gate 211, and thus a detailed description is deemed unnecessary. In the present disclosure, the material of the third semiconductor layer 312 may be similar to that of the first semiconductor layer 112 or the second semiconductor layer 212, and thus a detailed description is deemed unnecessary. In the present disclosure, the material of the third pixel electrode 32 may be similar to that of the first pixel electrode 12 or the second pixel electrode 22, and thus a detailed description is deemed unnecessary. In addition, in the present disclosure, other components and materials of the display device may be as described above and will not be described again here.

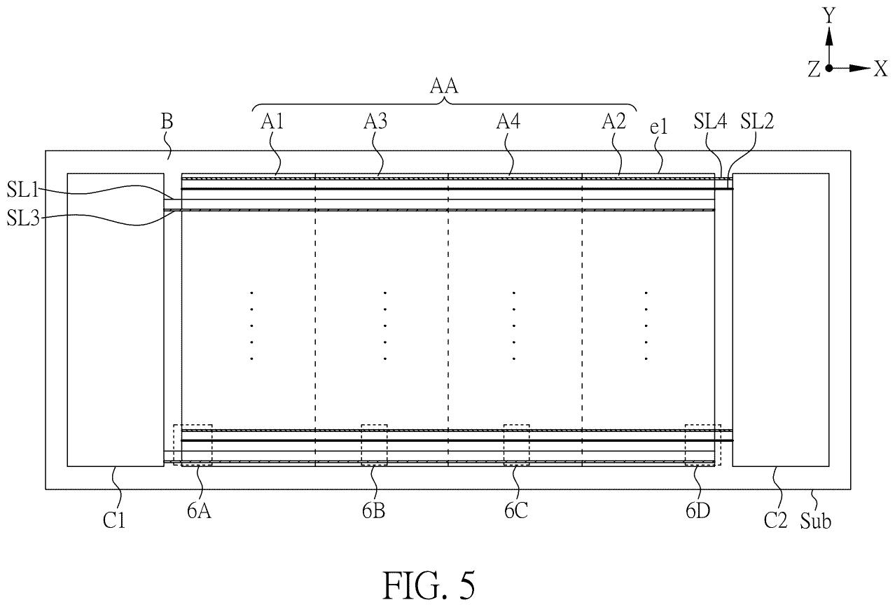

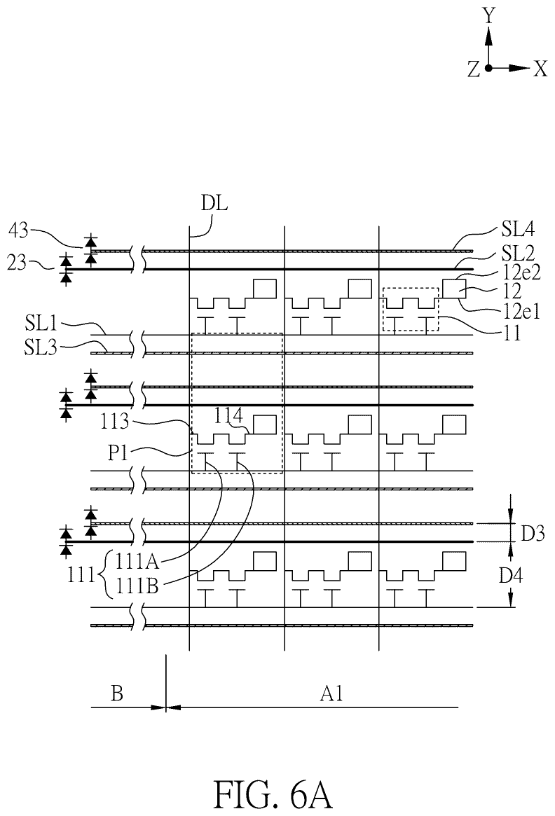

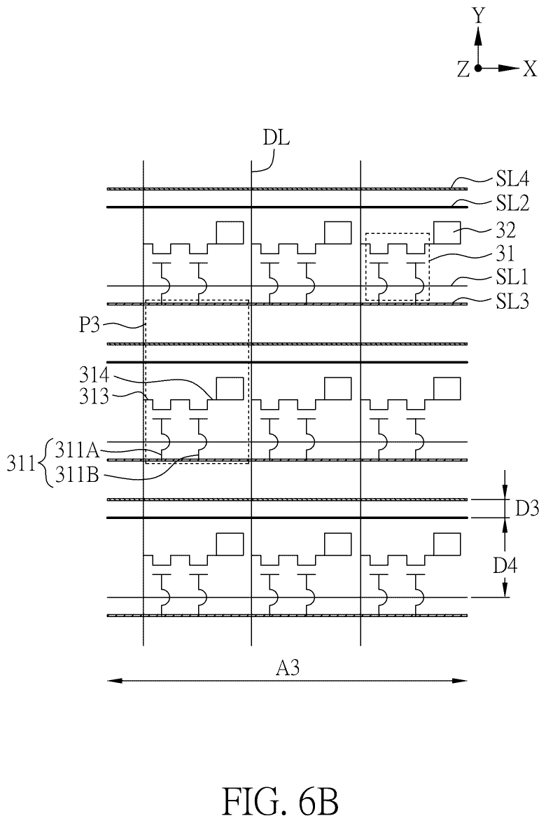

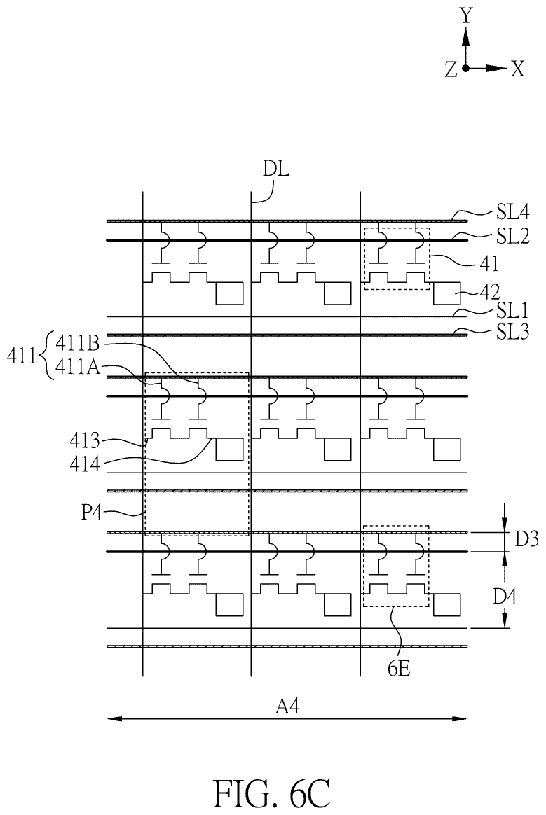

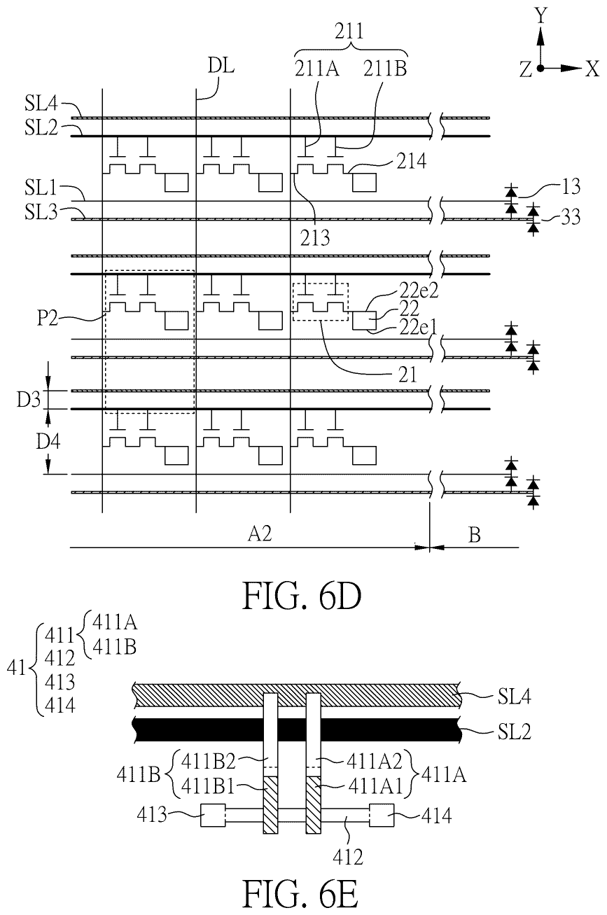

FIG. 5 is a schematic diagram of a display device according to an embodiment of the present disclosure, FIG. 6A to FIG. 6D are partial enlarged views of FIG. 5, and FIG. 6E is a partial enlarged view of FIG. 6D, wherein the display device of FIG. 5 is similar to that of FIG. 3 except for the following differences. In addition, for convenience of explanation, some components are omitted from the figures.

In one embodiment of the present disclosure, as shown in FIG. 5, the active area AA of the substrate Sub may include a fourth area A4, wherein the third area A3 of the active area AA is disposed between the first area A1 and the fourth area A4, and the fourth area A4 is disposed between the third area A3 and the second area A2. The display device further includes: a plurality of fourth scan lines SL4 extending along the first direction X in the active area AA, wherein the fourth scan lines SL4 are electrically connected to the second driving circuit C2.

In one embodiment of the present disclosure, as shown in FIG. 6A to FIG. 6D, in the second direction Y, one of the second scan lines SL2 is disposed between one of the first scan lines SL1 and one of the fourth scan lines SL4, and the distance D3 between the one of the second scan lines SL2 and the one of the fourth scan lines SL4 is smaller than the distance D4 between the one of the second scan lines SL2 and the one of the first scan lines SL1. In more detail, in the second direction Y, the first scan line SL1 and the fourth scan line SL4 are respectively disposed on two sides of the second scan line SL2, wherein there is a distance D3 between the fourth scan line SL4 adjacent to the second scan line SL2 and the second scan line SL2, and there is a distance D4 between the first scan line SL1 adjacent to the second scan line SL2 and the second scan line SL2, where the distance D3 is smaller than the distance D4.

In one embodiment of the present disclosure, as shown in FIG. 5, the active area AA has an edge e1 parallel to the first direction X, wherein the length of at least one of the first scan line SL1, the second scan line SL2, the third scan line SL3 and the fourth scan line SL4 is greater than ¾ of the length of the edge e1, but the present disclosure is not limited thereto.

In one embodiment of the present disclosure, as shown in FIG. 6A to FIG. 6D, a plurality of data lines DL and a plurality of fourth scan lines SL4 are intersected to form a plurality of fourth display units P4, and the fourth display units P4 are disposed in the fourth area A4 of the active area AA (as shown in FIG. 5). The first display unit P1 are respectively electrically connected to the first scan lines SL1, and electrically separated from the second scan lines SL2, the third scan lines SL3 and the fourth scan lines SL4. The second display units P2 are respectively electrically connected to the second scan lines SL2, and electrically separated from the first scan lines SL1, the third scan lines SL3 and the fourth scan lines SL4. The third display unit P3 are respectively electrically connected to the third scan lines SL3, and electrically separated from the first scan lines SL1, the second scan lines SL2 and the fourth scan lines SL4. The fourth display units P4 are respectively electrically connected to the fourth scan line SL4, and electrically separated from the first scan line SL1, the second scan line SL2 and the third scan lines SL3.

In the present disclosure, by transmitting signals to the first display units P1 through the first scan lines SL1 electrically connected to the first driving circuit C1, transmitting signals to the second display units P2 through the second scan lines SL2 electrically connected to the second driving circuit C2, transmitting signals to the third display units P3 through the third scan lines SL3 electrically connected to the first driving circuit C1, and transmitting signals to fourth display units P4 through the fourth scan lines SL4 electrically connected to the second driving circuit C2, it is able to realize, in the same display device, the effect of partitioning display through the first display units P1 disposed in the first area A1, the second display units P2 disposed in the second area A2, the third display units P3 disposed in the third area A3 and the fourth display units P4 disposed in the fourth area A4. In other words, in the same display device, the first display units P1 disposed in the first area A1, the second display units P2 disposed in the second area A2, the third display units P3 disposed in the third area A3, and the fourth display units P4 disposed in the fourth area A4 may respectively display different patterns. When the components or display units in any one or more of the first area A1, the second area A2, the third area A3 and the fourth area A4 of the active area AA are defective, the display units in other areas may still display images.

In this embodiment, as shown in FIG. 5, the fourth scan line SL4 is exemplified by being electrically connected to the second driving circuit C2. However, in other embodiments, the fourth scan line SL4 may be electrically connected to the first driving circuit C1 so that signals may be transmitted from the first driving circuit C1 to the fourth display unit P4 via the fourth scan line SL4 (as shown in FIG. 6C).

In one embodiment of the present disclosure, as shown in FIG. 6C, one of the fourth display units P4 may include: a fourth transistor 41; and a fourth pixel electrode 42, wherein the fourth transistor 41 is electrically connected to the fourth pixel electrode 42. In more detail, as shown in FIG. 6E, the fourth transistor 41 may include: a fourth gate 411, a fourth semiconductor layer 412, a seventh electrode 413 and an eighth electrode 414, wherein the fourth gate 411 is electrically connected to one of the fourth scan lines SL4 and overlaps with a portion of the fourth semiconductor layer 412. In addition, as shown in FIG. 6C and FIG. 6E, the seventh electrode 413 is electrically connected to one of the data lines DL, and the eighth electrode 414 is electrically connected to the fourth pixel electrode 42.

In one embodiment of the present disclosure, as shown in FIG. 6C and FIG. 6E, the fourth gate 411 may include branch portions 411A and 411B, and the branch portions 411A and 411B are respectively electrically connected to the same one of the fourth scan line SL4, and overlap with a portion of the fourth semiconductor layer 412. In more detail, as shown in FIG. 6E, the branch portion 411A includes a first portion 411A1 and a second portion 411A2, and the branch portion 411B includes a third portion 411B1 and a fourth portion 411B2, wherein the first portion 411A1 and the third portion 411B1 respectively overlap with a portion of the fourth semiconductor layer 412, the second portion 411A2 spans the second scan line SL2 to be electrically connected to the fourth scan line SL4 and the first portion 411A1, and the fourth portion 411B2 spans the second scan line SL2 to be electrically connected to the fourth scan line SL4 and the third portion 411B1. In the present disclosure, as shown in FIG. 6E, the fourth gate 411 is exemplified by a top gate structure, but the present disclosure is not limited thereto. In other embodiments, the fourth gate 411 may also be a bottom gate structure.

In the present disclosure, the materials of the first portion 411A1 and the third portion 411B1 may be different from the materials of the second portion 411A2 and the fourth portion 411B2. For example, the first portion 411A1 and the third portion 411B1 may include a metal material, an alloy thereof, or a combination thereof, and the second portion 411A2 and the fourth portion 411B2 may include a transparent conductive material. The suitable metal material may be, for example, gold, silver, copper, palladium, platinum, ruthenium, aluminum, cobalt, nickel, titanium, molybdenum, manganese or a combination thereof, but the present disclosure is not limited thereto. The suitable transparent conductive material may be, for example, indium zinc oxide (IZO), indium tin oxide (ITO), indium tin zinc oxide (ITZO), indium gallium zinc oxide (IGZO), aluminum zinc oxide (AZO) or a combination thereof, but the present disclosure is not limited thereto.

In one embodiment of the present disclosure, as shown in FIG. 6A, the display device may include a fourth electrostatic discharge protection structure 43, which is disposed in the peripheral area B of the substrate Sub (as shown in FIG. 5) and electrically connected to the fourth scan line SL4. In one embodiment of the present disclosure, as shown in FIG. 5 and FIG. 6A, in the first direction X, the fourth electrostatic discharge protection structure 43 is disposed between the first driving circuit C1 and the first area A1. In the present disclosure, the fourth electrostatic discharge protection structure 43 may be similar to the first electrostatic discharge protection structure 13 or the second electrostatic discharge protection structure 23, and may be used to release the electrostatic charges generated by the display device, which will not be described again here.

In the present disclosure, the fourth scan line SL4 may be the same layer or a different layer from the first scan line SL1, the second scan line SL2, and/or the third scan line SL3, and the material of the fourth scan line SL4 is similar to that of the first scan line SL1 or the second scan line SL2, so that a detailed description is deemed unnecessary. In the present disclosure, the material of the fourth gate 411 may be similar to that of the first gate 111 or the second gate 211, and thus a detailed description is deemed unnecessary. In the present disclosure, the material of the fourth semiconductor layer 412 may be similar to that of the first semiconductor layer 112 or the second semiconductor layer 212, and thus a detailed description is deemed unnecessary. In the present disclosure, the material of the fourth pixel electrode 42 may be similar to that of the first pixel electrode 12 or the second pixel electrode 22, and thus a detailed description is deemed unnecessary. In addition, in the present disclosure, other components and materials of the display device may be as described above and will not be described again here.

In the present disclosure, a plurality of scan lines are provided on the substrate and the scan lines may be electrically connected to different driving circuits, so that the effect of partitioning display can be achieved by using different driving circuits to drive the display units.

The aforementioned specific embodiments should be interpreted as merely illustrative, and not limiting the rest of the present disclosure in any way, and the features of different embodiments may be mixed and matched as long as they do not conflict with each other.

1. A display device, comprising:
a substrate including an active area having a first area and a second area;
a first driving circuit disposed adjacent to the first area of the active area;
a second driving circuit disposed adjacent to the second area of the active area;
a plurality of first scan lines extending along a first direction in the active area, wherein the first scan lines are electrically connected to the first driving circuit;
a plurality of second scan lines extending along the first direction in the active area, wherein the second scan lines are electrically connected to the second driving circuit;
a plurality of first display units disposed in the first area of the active area, wherein the first display units are respectively electrically connected to the first scan lines and electrically separated from the second scan lines; and
a plurality of second display units disposed in the second area of the active area, wherein the second display units are respectively electrically connected to the second scan lines and are electrically separated from the first scan lines,
wherein the first scan lines and the second scan lines are disposed in an interlaced manner and, in the first direction, the active area is disposed between the first driving circuit and the second driving circuit.

2. The display device as claimed in claim 1, wherein, in the first direction, the first area of the active area is disposed between the second area of the active area and the first driving circuit, and the second area of the active area is disposed between the first area of the active area and the second driving circuit.

3. The display device as claimed in claim 1, wherein one of the first display units has a first pixel electrode and a first transistor electrically connected to the first pixel electrode, the first pixel electrode has a first edge and a second edge opposite to the first edge, one of the first scan lines is disposed adjacent to the first edge and electrically connected to the first transistor, and one of the second scan lines is disposed adjacent to the second edge.

4. The display device as claimed in claim 3, wherein the first transistor includes a first gate, a first semiconductor layer, a first electrode and a second electrode, and the first gate is electrically connected to the one of the first scan lines and overlaps with the first semiconductor layer.

5. The display device as claimed in claim 4, further comprising a plurality of data lines extending along a second direction in the active area, the first direction being different from the second direction, wherein the first electrode is electrically connected to one of the data lines, and the second electrode is electrically connected to the first pixel electrode.

6. The display device as claimed in claim 1, further comprising a plurality of third display units, wherein the active area includes a third area disposed between the first area and the second area of the active area, and the third display units are disposed in the third area of the active area.

7. The display device as claimed in claim 6, further comprising a plurality of third scan lines extending along the first direction in the active area, wherein the third scan lines are electrically connected to the first driving circuit, and the third display units are respectively electrically connected to the third scan lines.

8. The display device as claimed in claim 7, further comprising a plurality of data lines extending along a second direction in the active area, the first direction being different from the second direction, wherein, in the second direction, one of the first scan lines is disposed between one of the second scan lines and one of the third scan lines, and the distance between the one of the first scan lines and the one of the third scan lines is smaller than the distance between the one of the first scan lines and the one of the second scan lines.

9. The display device as claimed in claim 7, wherein one of the third display units has a third transistor including a third gate and a third semiconductor layer, the third gate includes a first portion and a second portion, the first portion overlaps with the third semiconductor layer, and the second portion spans one of the first scan lines to be electrically connected to one of the third scan lines and the first portion, where the second portion includes a transparent conductive material.

10. The display device as claimed in claim 1, wherein the active area has an edge parallel to the first direction, wherein a length of at least one of the first scan lines and the second scan lines is greater than ¾ of a length of the edge.

11. The display device as claimed in claim 4, wherein the first gate includes two branch portions.

12. The display device as claimed in claim 5, wherein one of the second display units has a second pixel electrode and a second transistor electrically connected to the second pixel electrode, the second pixel electrode has a first edge and a second edge opposite to the first edge, one of the second scan lines is disposed adjacent to the second edge and electrically connected to the second transistor, and one of the first scan lines is disposed adjacent to the first edge.

13. The display device as claimed in claim 12, wherein the second transistor includes a second gate, a second semiconductor layer, a third electrode and a fourth electrode, and the second gate is electrically connected to the one of the second scan lines and overlaps with the second semiconductor layer.

14. The display device as claimed in claim 13, wherein the third electrode is electrically connected to one of the data lines, and the fourth electrode is electrically connected to the second pixel electrode.

15. The display device as claimed in claim 13, wherein the second gate includes two branch portions.

16. The display device as claimed in claim 1, further comprising an electrostatic discharge protection structure disposed in a peripheral area of the substrate and electrically connected to one of the second scan lines, wherein, in the first direction, the electrostatic discharge protection structure is disposed between the first driving circuit and the first area.

17. The display device as claimed in claim 9, further comprising a plurality of fourth display units, wherein the active area includes a fourth area disposed between the third area and the second area of the active area, the third area of the active area is disposed between the first area and the fourth area, and the fourth display units are disposed in the fourth area of the active area.

18. The display device as claimed in claim 17, further comprising a plurality of fourth scan lines extending along the first direction in the active area, wherein the fourth scan lines are electrically connected to the second driving circuit, and the fourth display units are respectively electrically connected to the fourth scan lines.

19. The display device as claimed in claim 18, wherein one of the fourth display units has a fourth transistor including a fourth gate and a fourth semiconductor layer, the fourth gate includes a first branch portion and a second branch portion that are respectively electrically connected to the same one of the fourth scan lines and overlap with a portion of the fourth semiconductor layer.

20. The display device as claimed in claim 19, wherein the first branch portion includes a first portion and a second portion, the second branch portion includes a third portion and a fourth portion, the first portion and the third portion respectively overlap with the fourth semiconductor layer, the second portion spans one of the second scan lines to be electrically connected to one of the fourth scan lines and the first portion, and the fourth portion spans one of the second scan lines to be electrically connected to one of the fourth scan lines and the third portion.
